(19) United States
(12) Patent Application Publication
(10) Pub. No.: US 2026/0025621 A1
(43) Pub. Date: Jan. 22, 2026

(54) MEMS WITH ADJUSTED SEMICONDUCTOR BEHAVIOR

(71) Applicants: FRAUNHOFER-GESELLSCHAFT ZUR FÖRDERUNG DER ANGEWANDTEN FORSCHUNG E.V., München (DE); ROBERT BOSCH GMBH, Stuttgart (DE)

(72) Inventors: Sergiu LANGA, Dresden (DE); Robert Poser, Dresden (DE)

(21) Appl. No.: 19/269,630

(22) Filed: Jul. 15, 2025

(30) Foreign Application Priority Data
Jul. 18, 2024 (DE) 102024206778.4

(51) Int. Cl. H04R 19/00; B81B 3/00

(52) U.S. Cl. CPC H04R 19/005; B81B 3/0056; B81B 2201/0257; B81B 2203/0136; B81B 2203/04; H04R 2201/003

(57) ABSTRACT

An MEMS has a movable element and a drive device having a first doped semiconductor electrode of the movable element and a second doped semiconductor electrode which is arranged opposite to the first semiconductor electrode and configured to generate while generating a first change zone of charge carriers in the first semiconductor electrode and a second change zone of charge carriers in the second semiconductor electrode.

### CROSS-REFERENCE TO RELATED APPLICATION

This application claims priority from German Application No. 10 2024 206 778.4, which was filed on Jul. 18, 2024, and is incorporated herein by reference in its entirety.

### TECHNICAL FIELD

The present invention relates to MEMS with an adjusted semiconductor behavior, in particular the implementation of accumulation zones and space charge zones for controlling a movable element. The present invention further relates to a control-dependent doping of the substrates.

### BACKGROUND OF THE INVENTION

In MEMS with a movable element, such as can be used, for example, for moving a fluid, semiconductor materials, in particular doped semiconductor materials, can be used to implement electrical actuation. Examples of this are electrode arrangements for electrostatic or electrodynamic excitations using electrostatic or electrodynamic forces. Such electrode arrangements can be provided at least in parts using doped semiconductor materials.

Among other things, but not limited to this, a reproducible and symmetrical deflection of movable elements in an MEMS is of advantage for some implementations. An MEMS loudspeaker and, complementary thereto, an MEMS microphone can be considered as a non-limiting example of this, in which the movable element for interacting with a fluid, such as the air, is advantageously deflected uniformly in one and the opposite direction in order to be able to generate low-interference sound waves in the fluid.

Such a symmetrical operation may also be deliberately deviated from for some embodiments, wherein this is still within the frame of requirements in which good controllability of the movement of the movable element takes place.

Accordingly, MEMS with movable elements the movement of which can be actuated with little interference are desirable.

The object underlying the present invention is to provide MEMS with a movable element which allow low-interference actuatability of the movable element.

### SUMMARY

According to an embodiment, an MEMS may have: a movable element; and a drive device having a first doped semiconductor electrode of the movable element and a second doped semiconductor electrode which is arranged opposite to the first semiconductor electrode and configured to generate an electrostatic force between the first semiconductor electrode and the second semiconductor electrode while generating a first change zone of charge carriers in the first semiconductor electrode and a second change zone of charge carriers in the second semiconductor electrode for deflecting the movable element.

According to another embodiment, an MEMS may have: a movable element; and a drive device having a first electrode of the movable element and a second electrode formed as a doped semiconductor electrode which is arranged opposite to the first electrode and configured to generate an electrostatic force between the first electrode and the second electrode while generating a first change zone of charge carriers in the second electrode and for deflecting the movable element.

A core idea of the present invention is having recognized that interferences in the movement of an MEMS arise due to change zones of different kinds for the movement in different directions in a semiconductor material and that these interferences can advantageously be avoided if MEMS are configured such that change zones of the same kind are arranged opposite to one another and, optionally, next to one another.

According to an embodiment, an MEMS comprises a movable element and a drive device comprising a first doped semiconductor electrode of the movable element and a second doped semiconductor electrode which is arranged opposite to the first semiconductor electrode and is configured to generate an electrostatic force between the first semiconductor electrode and the second semiconductor electrode while generating a first change zone of charge carriers in the first semiconductor electrode and a second change zone of charge carriers in the second semiconductor electrode for deflecting the movable element. Adjustment of the change zones allows an adjustment of the deflection behavior.

In some implementations, the drive device is implemented with the first doped semiconductor electrode and the second doped semiconductor electrode as well as a third doped semiconductor electrode. The first doped semiconductor electrode is part of the movable element or arranged thereon, and the second doped semiconductor electrode and the third doped semiconductor electrode are arranged opposite to the first semiconductor electrode. The doped semiconductor electrodes are configured to alternately generate an electrostatic force between the first semiconductor electrode and the second semiconductor electrode on the one hand, and between the first semiconductor electrode and the third semiconductor electrode on the other hand, while generating a first change zone of charge carriers in the first semiconductor electrode, generating a second change zone of charge carriers in the second semiconductor electrode, and generating a third change zone of charge carriers in the third semiconductor electrode for deflecting the movable element. The second change zone and the third change zone are formed to be of the same kind. The fact that the second change zone and the third change zone are of the same kind allows equal influencing of the generated force and of the movement through the change zones.

According to an embodiment, an MEMS comprises a movable element and a drive device. The drive device comprises a first electrode of the movable element and a second electrode formed as a doped semiconductor electrode which is arranged opposite to the first electrode and is configured to generate an electrostatic force between the first electrode and the second electrode while generating a first change zone of charge carriers in the second electrode and for deflecting the movable element, which also allows an advantageous setting of the deflection behavior.

In some implementations, the drive device comprises a first electrode of the movable element which can be part of the movable element or can be arranged therein. Furthermore, the drive device comprises a second electrode which is formed as a doped semiconductor electrode, and a third electrode which is formed as a doped semiconductor electrode. The second electrode and the third electrode are arranged opposite to the first electrode and are configured to alternately generate an electrostatic force between the first electrode and the second electrode on the one hand, and between the first electrode and the third electrode on the other hand, while generating a first change zone of charge carriers in the second electrode and a second change zone of charge carriers in the third electrode for deflecting the movable element. The first change zone and the second change zone are formed differently from one another; in this embodiment, the different change zones of the second electrode and the third electrode are used for homogeneous movement.

### BRIEF DESCRIPTION OF THE DRAWINGS

Particularly advantageous embodiments of the present invention will be explained below referring to the attached drawings, in which:

FIGS. 1A-C show schematic side sectional views of different possible implementations of MEMS according to embodiments;

FIG. 2 shows a schematic side sectional view of an MEMS with a cover drive on both sides according to an embodiment;

FIG. 3 shows a schematic side sectional view of a known MEMS component;

FIG. 4 shows a schematic side sectional view of a part of an MEMS according to an embodiment which overcomes the disadvantages of the MEMS of FIG. 3;

FIGS. 5A-B show schematic diagrams of an, for example, n-doped semiconductor material, for instance comprising phosphorus dopants;

FIGS. 6A-B show schematic diagrams of an, for example, p-doped semiconductor material, for instance comprising boron dopants;

FIGS. 7A-D show schematic side sectional views of MEMS according to embodiments in which electrodes are doped differently;

FIGS. 8A-B show schematic side sectional views of MEMS according to embodiments in which opposite electrodes are doped to be of the same kind;

FIGS. 9A-B show a respective configuration of semiconductor electrodes and of the movable element in accordance with FIGS. 8A-B with a changed actuation voltage according to an embodiment;

FIG. 10 shows a schematic top view of an MEMS formed as a comb drive according to an embodiment; and

FIGS. 11A-B show schematic side sectional views of MEMS according to embodiments in which electrodes for driving a movable element form different change zones.

### DETAILED DESCRIPTION OF THE INVENTION

Before embodiments of the present invention will be explained in more detail below referring to the drawings, it is pointed out that identical, elements, objects and/or structures or those of equal function or equal effect are provided with the same reference signs in the different FIGS. so that the description of these elements illustrated in different embodiments is interchangeable or mutually applicable.

Embodiments described below will be described in connection with a plurality of details. However, embodiments can also be implemented without these detailed features. Furthermore, for the sake of comprehensibility, embodiments will be described using block diagrams as a replacement for a detailed illustration. Furthermore, details and/or features of individual embodiments may be easily combined with one another as long as it is not explicitly described to the contrary.

Embodiments described below relate to MEMS with a movable element and a drive device in which an electrode formed on the movable element, in the movable element or with the movable element can be a doped semiconductor electrode or can also be formed differently in alternative implementations, for instance using metallic materials. According to embodiments, electrodes for interaction with this electrode are or comprise doped semiconductor electrodes, wherein semiconductor electrodes can react with a movement of charge carriers when a potential is applied and when an electrostatic or electrodynamic force is generated. Embodiments are based on knowing this effect and on measures in order to make these effects usable and, in particular with regard to MEMS loudspeakers, to adapt them to one another in such a way that the movement of the movable element in different directions can take place identically or symmetrically, which is of advantage in MEMS loudspeakers for the quality of the loudspeaker signal obtained.

Embodiments of the present invention are described on the basis of a multilayer MEMS structure, but the invention is not limited to this.

Embodiments relate to the enrichment or accumulation and to the depletion of charge carriers in semiconductor materials. In the context of embodiments described herein, the term space charge region is used synonymous with depletion region. In contrast, accumulation regions or accumulation zones can exhibit an enrichment of movable charge carriers.

WO 2022/117197 A1 describes an MEMS component with actuators which are arranged symmetrically over the electrode gaps. This allows symmetrical actuation and an approximately linear movement of the actuators.

WO 2021/093950 describes a laterally deflectable MEMS element which consists of three partial elements in order to allow high and adjustable linearity.

EP 3 867 191 A1 discloses how a device of an MEMS may look so that the deflections are already linearized by the mechanical design. This is achieved by selecting a symmetrical electrode arrangement whose symmetry relates precisely to the effect of the non-linearities. As a result, these cancel themselves out completely or partially in at least one specific operating range. The disadvantage of these known concepts is that the space charge zones and accumulation zones in the system are not influenced, controlled or taken into account actively.

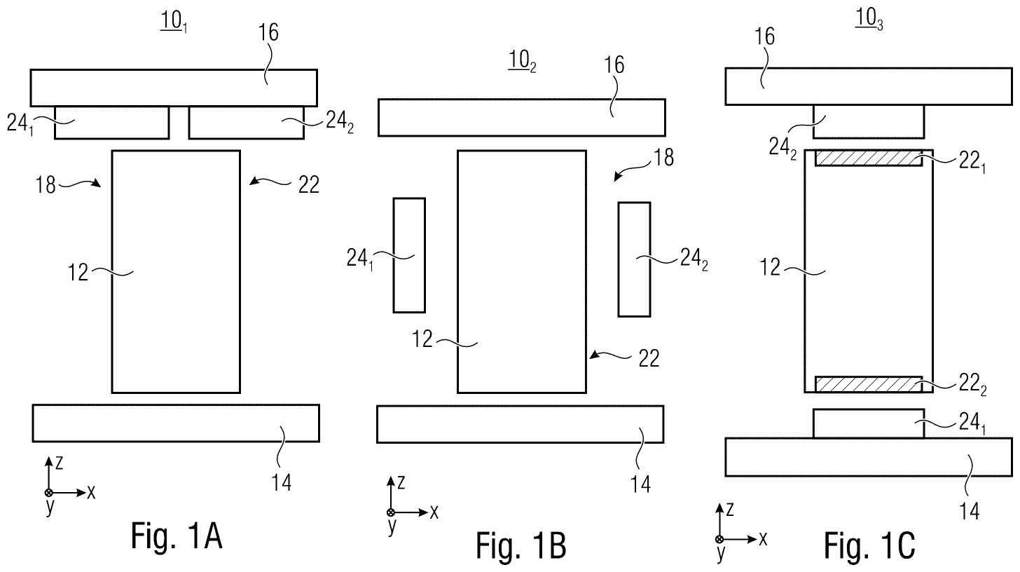

FIG. 1A shows a schematic side sectional view of a possible implementation of an MEMS 10₁ according to an embodiment. The MEMS 10₁ comprises a movable element 12 which can be arranged in a cavity of the MEMS 10₁. The cavity can be delimited, for example, by a bottom substrate or a bottom wafer 14 on a first side and a lid substrate or a lid wafer 16 on an opposite other side. The movable element 12 can be arranged between the bottom wafer 14 and the lid wafer 16 and can be deflectable along a stacking direction z and/or perpendicular thereto, for instance along an x-direction. The MEMS 10₁ comprises a drive device 18 for deflecting the movable element 12. For this purpose, an electrode 22 is provided which is fixedly connected to the movable element 12, forms part of the movable element 12 and/or can be arranged on the movable element 12. Thus, for example, the electrode 22 can comprise a metallic material which is deposited on the movable element 12, for instance comprising a semiconductor material, a polymer, a ceramic or the like. Alternatively or additionally, the movable element 12 can also comprise or be formed a metallic material so that the electrode 22 is formed from the structure of the movable element 12. A similar approach is made possible by forming the movable element 12 to comprise a doped semiconductor material, which allows an electrical potential to be applied to the movable element 12 in order to use the movable element 12 as an electrode. Such a doping of semiconductor material of the movable element 12 can also take place only in regions so that the electrode 22 can be provided only in regions of the movable element 12. Electrically conductive structures, for instance doped semiconductor materials and/or metallic materials, can be arranged on a surface of the movable element 12 or can be embedded or buried in the structure of the movable element 12.

The drive device 18 further comprises doped semiconductor electrodes 24₁ and 24₂ which are configured to be supplied with an electrical potential. The movable element and/or the movable electrode 22 can be arranged opposite to the not necessarily stationary electrodes 24₁ and 24₂. Thus, for example, a first potential difference between the electrode 22 and the electrode 24₁ can be used for a deflection along a positive or negative x-direction and another potential difference between the electrodes 22 and 24₂ can be used for a deflection along an opposite direction. It is to be noted that in the context of embodiments described herein, only one of the electrodes 24₁ or 24₂ can also be arranged. Such a drive device comprises a first doped semiconductor electrode 22 of the movable element 12 and a second doped semiconductor electrode 24₁ or 24₂, for instance as an asymmetric comb drive. In this implementation, the second doped semiconductor electrode is arranged opposite to the first semiconductor electrode 22 and is configured to generate an electrostatic force between the first semiconductor electrode and the second semiconductor electrode 24₁ while generating a first change zone of charge carriers in the first semiconductor electrode 22 and a second change zone of charge carriers in the second semiconductor electrode 24₁ for deflecting the movable element 12. In an advantageous implementation, this setup is extended by the third electrode. The third doped semiconductor electrode 24₂ is then arranged opposite to the first semiconductor electrode 22, for example together with the second doped semiconductor electrode, wherein the semiconductor electrodes are configured to alternately generate an electrostatic force between the first semiconductor electrode and the second semiconductor electrode on the one hand, and between the first semiconductor electrode and the third semiconductor electrode on the other hand, while generating the first change zone of charge carriers in the first semiconductor electrode and the second change zone of charge carriers in the second semiconductor electrode and a third change zone of charge carriers in the third semiconductor electrode for deflecting the movable element. The second change zone and the third change zone are of the same kind.

FIG. 1B shows a schematic side sectional view of an MEMS 10₂ in connection with another configuration of embodiments. Here, too, the movable element 12 is arranged between the semiconductor electrodes 24₁ and 24₂ and the drive device 18 is configured to provide an electrostatic force between the electrodes 22 and 24₁ or 22 and 24₂ in order to deflect the movable element 12 along a positive or negative x-direction.

FIG. 1C shows a schematic side sectional view of an MEMS 10₃ in connection with embodiments discussed herein, in which the movable element 12 is arranged between the semiconductor electrodes 24₁ and 24₂, wherein the semiconductor electrode 24₁ is arranged on or in the bottom wafer 14, wherein in particular out-of-plane forces can be generated for deflecting the movable element 12 out of the x/y-plane. For this purpose, for example, a first and a second electrode 221 and 222 can be part of the movable element 12, however, this is not necessary. Thus, for example, the implementation of the movable element 12 from a doped semiconductor material or from a metallic material is conceivable, wherein the movable element 12 itself can provide a common electrode 22 for the semiconductor electrodes 24₁ and 24₂.

It follows from FIGS. 1A-C that a movement of the movable element 12 can take place in-plane as in FIGS. 1A and 1B and/or out-of-plane as shown in FIG. 1C. The arrangement of the semiconductor electrodes 24₁ and 24₂ is in this case neither limited to the number of two nor tied to a specific spatial position, nor is the electrode of the movable element necessarily a doped semiconductor electrode.

Embodiments allow the advantageous use of semiconductor electrodes 24₁ and 24₂ and at the same time high quality of an acoustic signal obtained in the case of actuation of the MEMS as a loudspeaker. The same effect is achieved when the MEMS is used as a sensor, for instance as a microphone or the like.

The explanations relating to FIGS. 1A-C in this case merely provide an exemplary structure for the described embodiments without restricting the arrangement of a lid wafer and/or bottom wafer or the like.

Embodiments are described herein as MEMS components with a layer stack which consist at least of a substrate layer and in which the electrodes and the passive elements are arranged. Further layers relate to a bottom, which can also be referred to as a handling wafer, and a lid, which is also referred to as a lid wafer. Both lid wafer and handling wafer can be connected to the substrate plane, the plane of the movable element, by means of material bonding, advantageously bonding, as a result of which acoustically sealed gaps can form in the component. In this gap, which can correspond to the device plane or the device wafer, the deformable components deform, in other words the deformation then takes place in-plane.

WO 2022/117197 A1 describes an MEMS with a so-called lid drive. The contents of WO 2022/117197 A1 are hereby fully incorporated into the present description. An elementary cell of a lid drive, see, for example, FIG. 1A or FIG. 1C, can be divided substantially into three elements. A fin or the movable element 12 and two electrodes. These three elements are electrically and spatially separated from one another and can assume or can be supplied with different electrical potentials. Semiconductor electrodes 241 and 242 can be placed, for example, above the fin, for instance (as a lid-wafer variation) and/or below the fin (as a bottom-wafer variation). A combination thereof is easily possible.

When a voltage is applied between the movable element/fin and electrode 24₁, the fin can move towards the electrode 24₁. When a voltage is applied between the fin and electrode 24₂, the fin can move towards the electrode 24₂, wherein reversed potentials can also cause a reversal of direction.

The electrodes 24₁ and 24₂ are considered in connection with embodiments discussed herein for the lid-wafer case and are sometimes referred to as lid electrode 1 and lid electrode 2, without limiting the embodiments to this. It is to be mentioned that terms such as top, bottom, left, right, front, rear and the like are interchangeable as desired in the light of a changed orientation of an object in space and merely serve for a better understanding of the embodiments.

This means that the relationships described herein for the lid-wafer case are easily considered as alternative or additionally also for the bottom-wafer case. For this purpose, the electrodes can be placed, for example, below the fin. In this case, the electrodes can be considered and referred to as electrodes.

An example of such a structure is shown by the schematic side sectional view of an MEMS 20 in FIG. 2. The movable element 12 here is arranged both between lid electrodes 24_{1.1} and 24_{1.2} and between bottom electrodes 24_{2.1} and 24_{2.2}. In an advantageous implementation, an actuating device 26 of the MEMS 20 is configured to provide one or more actuating signals 28 in order to provide or trigger potentials to the movable element 12 or the electrode 22 and the electrodes 24_{1.1} to 24_{2.2}. The actuating device 26 can easily also be an external element which can be coupled to the electrodes by means of an interface.

For a particularly high-quality sound signal which can be generated by means of the MEMS 20 and/or for a particularly low-interference sensor signal, it may be of advantage to apply identical potentials to the electrodes 24_{1.1} and 24_{2.1} on the one hand and to the electrodes 24_{1.2} and 24_{2.2} on the other hand. However, the use of semiconductor electrodes 24_{1.1} to 24_{2.2} in this case results in effects which can lead to undesired interferences in the sound signal and/or electrical signal in known structures. It is first of all also pointed out that generating the electrostatic forces for deflecting and in particular the alternating actuation is not to be understood as meaning that the respective other electrode is to be connected without potential. Rather, it is also possible to simultaneously apply different electrical voltages between the movable element on the one hand and the electrode 1 and the electrode 2 on the other hand in order to obtain an increased degree of control over the fin movement, which can also be referred to as a balance mode.

The lid drive described herein can be used for applications which benefit particularly from a linear relationship between actuating signal and component reaction, such as, for instance, micro loudspeakers, um loudspeakers, which are operated or actuated in the so-called balance mode.

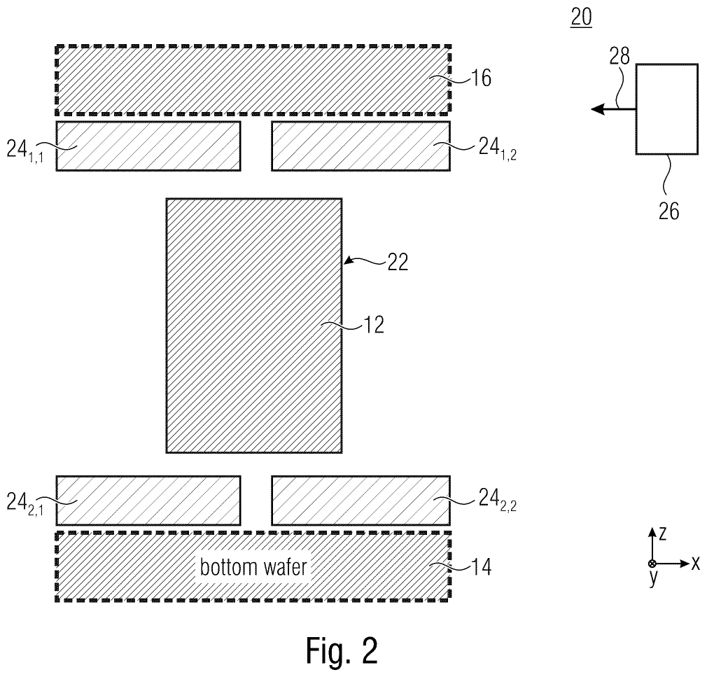

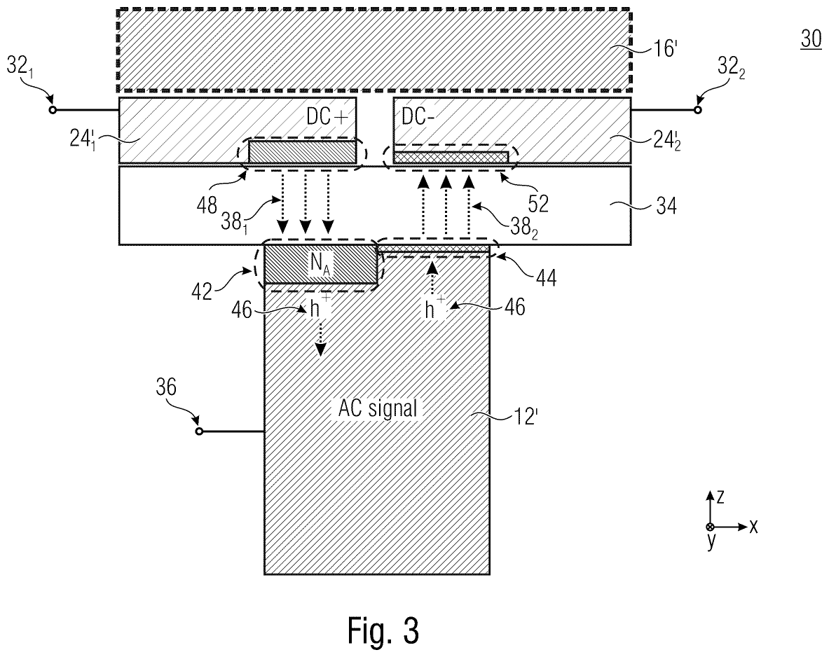

FIG. 3 shows a schematic side sectional view of a known MEMS component in which semiconductor electrodes 24′₁ and 24′₂ comprise an n-doped semiconductor material and are arranged on a p-doped lid wafer 16′. Potentials 32₁, also referred to as DC+, and 32₂, also referred to as DC−, can be applied to the semiconductor electrodes 24′₁ and 24′₂.

A dielectric 34, for example air or an oxide material, is arranged between the semiconductor electrodes 24′₁ and 24′₂ on the one hand and a movable element 12′, wherein, alternatively, vacuum could also be used for electrical insulation. The movable element 12′ is formed from a boron-doped p-semiconductor material so that electrical fields 38₁ and 38₂ are formed on the basis of an AC signal 36 applied to the movable element 12′. On account of different field propagation directions of the fields 38₁ and 38₂, for instance on account of the different voltage differences, a space charge zone 42 is formed opposite to the semiconductor electrode 24′₁ in the movable element 12′ and an accumulation zone 44 is formed opposite to the semiconductor electrode 24′₂. While charge carriers 46 can be underrepresented in the space charge zone 42 due to migration, they can be overrepresented in the accumulation zone 44 due to immigration. The charge carriers 46 can be holes in the p-doped semiconductor material. For n-doped semiconductors, the charge carriers can correspondingly be electrons.

The presence or formation of both regions, the space charge zone 42 and the accumulation zone 44, possibly at the same time, can result in symmetrical signals or signals DC+ and DC− having the same absolute amplitude generating different strong interactions or forces so that deviations in the movement of the movable element obtained can occur on the basis of this, since a space charge zone 48 of the semiconductor electrode 24′₁ and an accumulation zone 52 in the semiconductor electrode 24′₂ can provide corresponding forces.

In the context of the embodiments described herein, it can be assumed that in the case of an n-doped semiconductor material the electrons e⁻ form majority charge carriers and holes h⁺ form the minority charge carriers. An accumulation of e-in an n-doped semiconductor material such as the semiconductor electrode 24′₂ can result in a particularly high conductivity, as well as an accumulation of holes in the accumulation zone 44 in which holes h⁺ form the majority charge carriers and electrons e-form the minority charge carriers due to the p-doped property.

By contrast, the space charge zones 42 and 48 form a respective region of the movable element 12′ or of the semiconductor electrode 24′₁ which are conductive to a reduced extent or are not electrically conductive.

The situation shown is considered by the inventors to be unfavorable since the fin exhibits both a space charge zone and an accumulation zone. Furthermore, a respective semiconductor electrode, for example poly-Si, has either an accumulation zone 52 or space charge zone 48.

In an exemplary mode of operation, the AC signal 36 is provided in a voltage range of ±12 V and the DC voltages 32₁ and 32₂ can have, for example, a potential value of +19 V and −19 V.

In other words, FIG. 3 shows an elementary cell for a known lid drive as a cross-sectional image.

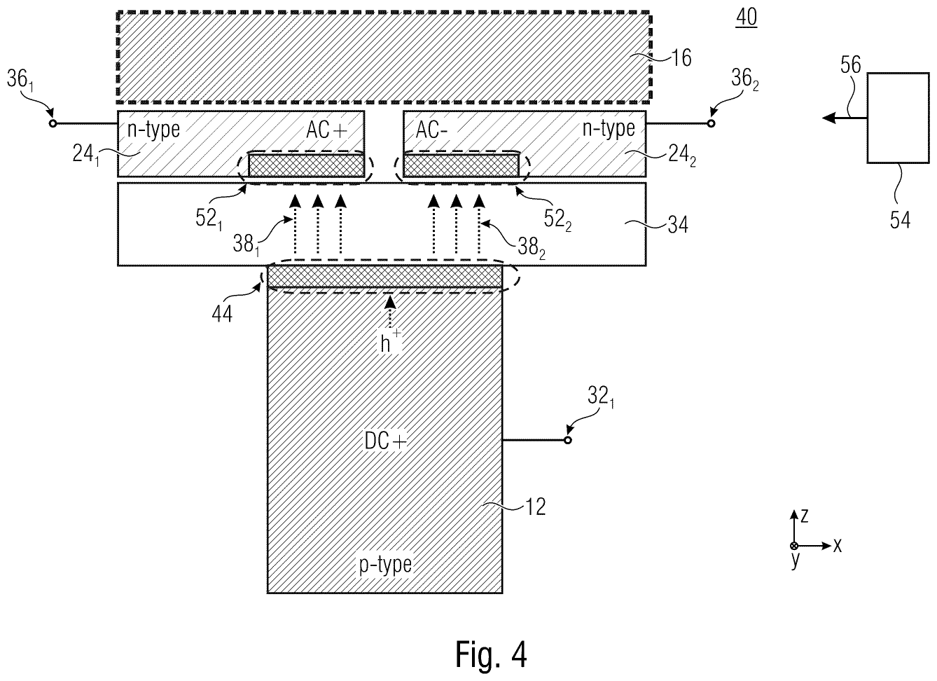

FIG. 4 shows a schematic side sectional view of a part of an MEMS 40 according to an embodiment which overcomes the disadvantages of the MEMS 30. The movable element 12 can be formed in accordance with the movable element 12′ and comprise, for example, a boron-doped semiconductor material of the same type. Likewise, the semiconductor electrodes 24₁ and 24₂ can be formed in accordance with the semiconductor electrodes 24′₁ and 24′₂ of the MEMS 30 and comprise, for example, an n-doped semiconductor material. The lid wafer 16 can be optionally, but not necessarily p-doped.

Unlike in MEMS 30, a positive DC voltage 32₁ would be applied to the movable element 12, for example. AC potentials, AC+/AC− 36₁ or 36₂, can be applied to the semiconductor electrodes 24₁ or 24₂. The potentials 36₁ and 36₂ can be understood here to be at least substantially inverted AC signals and can be identical with respect to an absolute value of the voltage and/or a frequency, for example identical signals with a 180° phase offset. A deviation with respect to the amplitude is possible, for example, in order to compensate for structural deviations affecting the movement of the movable element due to mutually different material rigidities.

The potential 32₁ at the movable element 12 can cause the accumulation zone 44 to form in the movable element 12. At the same time, applying the AC signals 36₁ and 36₂ can cause accumulation zones 52₁ and 52₂ to form in the semiconductor electrodes 24₁ and 24₂ so that the change zones of the semiconductor electrodes 24₁ and 24₂ formed by the accumulation zones 521 and 52₂ are of the same kind.

This allows a homogeneous implementation of the electrical fields 38₁ and 38₂. Such an effect would also be obtained if both accumulation zones 52₁ and 52₂ were space charge zones independently of whether the accumulation zone 44 remained an accumulation zone or else a space charge zone since the effect on the respective fields 38₁ and 38₂ would be the same, i.e. both fields would be influenced equally.

In an exemplary implementation, a voltage of approximately +19 V is applied to the movable element 12 and the voltage amplitudes of the AC signals 36₁ and 36₂ vary between +12 V and —12 V, wherein the signals 36₁ and 36₂ can be inverted with respect to each other.

In the context of embodiments described herein, an advantage for the operation of the MEMS is thus obtained with the arrangement and provision of change zones. A space charge zone or an accumulation zone is understood as a change zone. According to embodiments in connection with the MEMS 40, for example, the change zones of the semiconductor electrodes 24₁ and 24₂ are an accumulation zone or both are a space charge zone.

According to embodiments, the change zones of the semiconductor electrodes 24₁ and 24₂ and of the movable element 12 along a longitudinal extension direction y of the movable element are identical or invariable, i.e. a change as shown for the movable element 12′ of FIG. 3 along the transverse direction x is dispensed with. It is particularly advantageous for a change between change zones along the transverse extension direction x in the movable element 12, i.e. the electrode 22, to be dispensed with. This can optionally be further improved if the semiconductor electrodes 24₁ and 24₂ also do not have or form different change zones lying next to one another during operation.

As shown in FIG. 4, some embodiments provide for the change zones of the movable element 12 and of the semiconductor electrodes 241 and 242 to be of the same kind. This can also apply unchanged if a corresponding drive is provided in the bottom wafer 14. Optionally, however, it is also possible to use a complementary doping type there which results in a complementary manifestation of the change zone, for example a space charge zone adjacent to the bottom wafer.

The MEMS 40 can have an actuating device 54 which is configured to actuate the drive device. The actuating device 54 can be configured to apply a constant voltage or a DC potential to the semiconductor electrode of the movable element 12 and to apply alternating voltages, AC, to the semiconductor electrodes 24₁ and 24₂, wherein the alternating voltages 24₁ and 24₂ are particularly advantageously inverse to one another. Advantageous embodiments provide an actuating device in which a maximum absolute amplitude of the alternating voltages 36₁ and/or 36₂ is smaller than an absolute amplitude of the constant voltage, wherein the values of 12 V and 19 V are to be understood merely as examples. The increased absolute amplitude of the DC voltage relative to the AC voltage reliably allows the different change zones in the movable element 12′ to be obtained, as are shown in FIG. 3.

According to an embodiment, MEMS are provided in which at least two elements from the group of the first semiconductor electrode 24₁, the second semiconductor electrode 242 and the third semiconductor electrode have different doping types. In MEMS 40, the semiconductor electrodes 24₁ and 24₂ are n-doped while the movable element 12 or at least its electrode is p-doped. In this specific implementation, the semiconductor electrode of the movable element 12 has a different doping type with respect to the second and third semiconductor electrode, wherein it may also correspond to one of the two semiconductor electrodes 24₁ and 24₂.

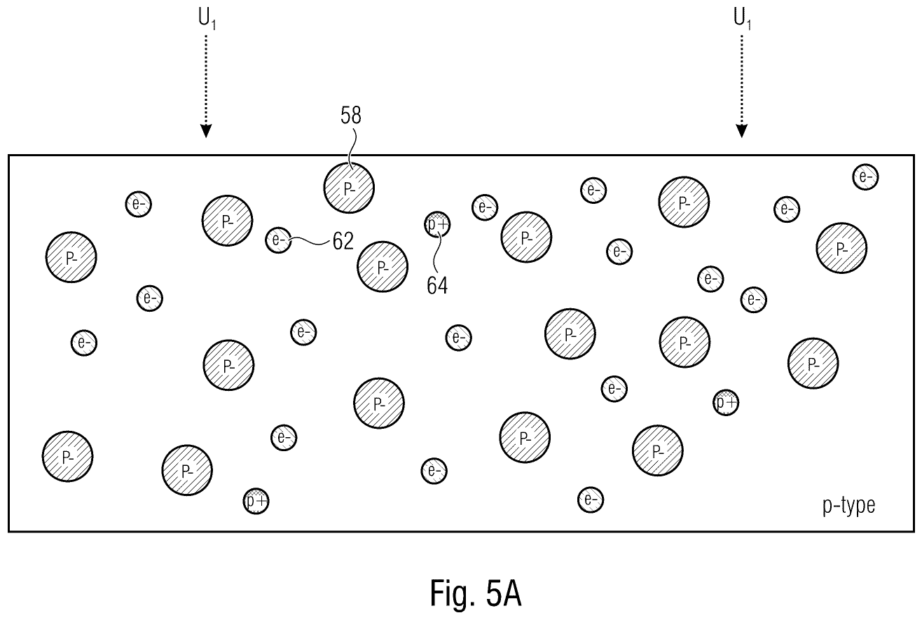

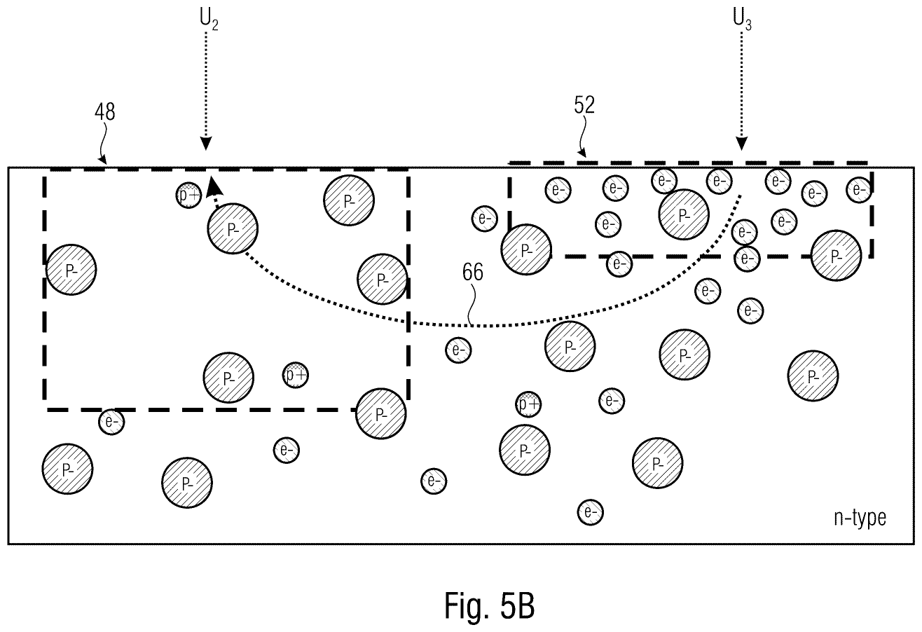

FIG. 5A shows a schematic diagram of an, for example, n-doped semiconductor material, for instance comprising phosphorus dopants (P) 58, in which there are electrons 62 and holes 64. A distribution at spatially the same voltage U₁, for instance 0 V, can change when different voltages U₂ and U₃ are applied in different regions, for instance —10 V and +10 V. This can result in accumulation zones 52 and space charge zones 48 being formed, for instance on the basis of a charge carrier migration 66.

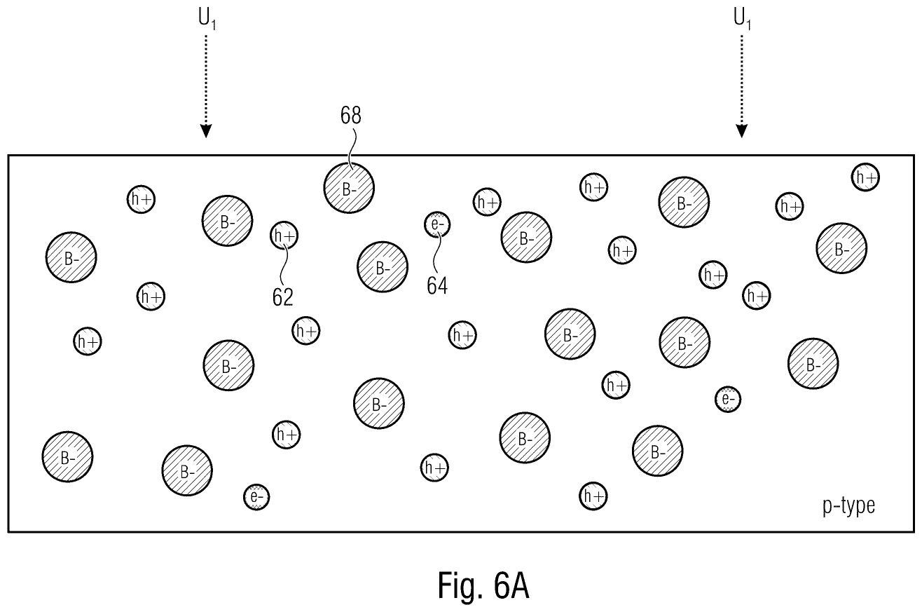

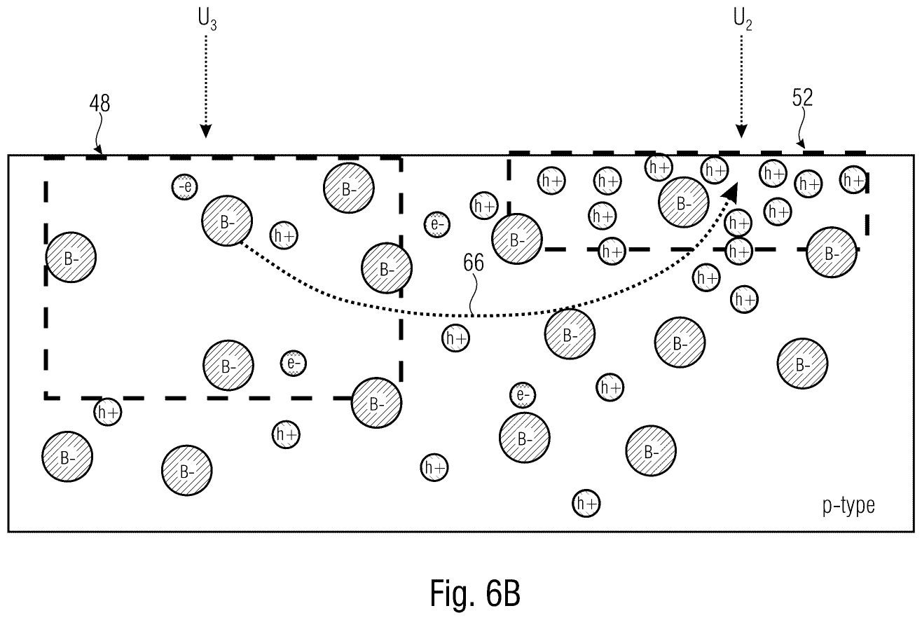

FIGS. 6A and 6B show a corresponding scenario in which the semiconductor material is p-doped using boron dopants 68. In comparison with the n-doping from FIG. 5B, the charge carrier migration 66 can take place in a different direction. Arrow directions of the arrows of the charge carrier migrations 66 can indicate the direction of the electrical field. If the applied potentials are interchanged, the arrow directions will thus also be interchanged.

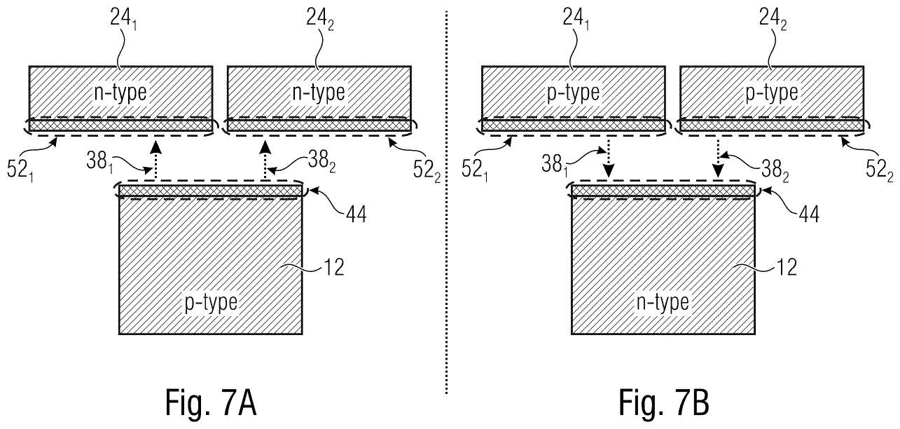

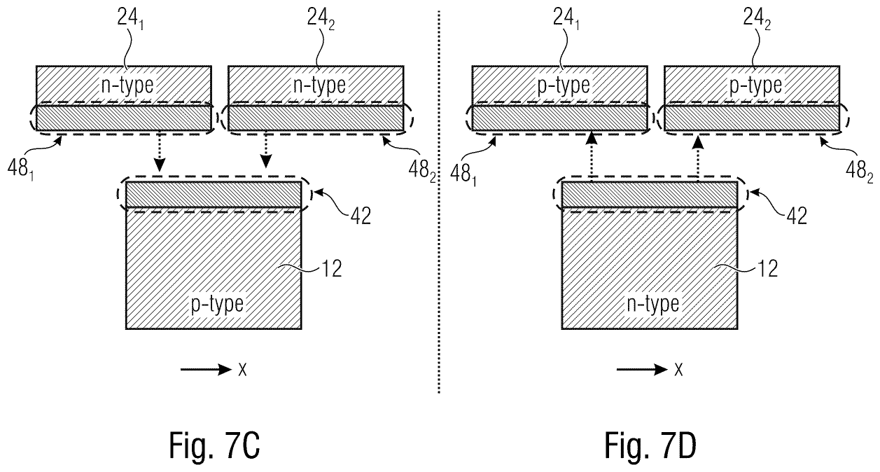

FIG. 7A shows a schematic block diagram of the movable element 12 and of the semiconductor electrodes 24₁ and 24₂ from an MEMS according to an embodiment. The configuration corresponds to the MEMS 40, wherein the semiconductor electrodes 24₁ and 24₂ are n-doped and at least the electrode of the movable element 12 is p-doped.

Here, a positive DC voltage is advantageously applied to the movable element 12.

FIG. 7B shows a configuration of the semiconductor electrodes 24₁ and 24₂ and of the movable element 12 according to an embodiment, which is inverted with respect to FIG. 7A. The semiconductor electrodes 24₁ and 24₂ are, for example, p-doped and the movable element 12 is n-doped. Even if the electrical fields 38₁ and 38₂ can be reversed by this, generation of the accumulation zones 44, 52₁ and 52₂ can be obtained by changing the aforementioned potentials in a corresponding manner. The change can relate to a positive DC voltage (DC+) being applied to the movable element 12 in FIG. 7A being applied to the movable element 12 and to a negative DC voltage (DC−) in FIG. 7B, for example, in order to obtain an accumulation. On the basis of the n-type doping, a negative DC voltage is advantageously applied to the movable element 12 in order to generate the accumulation zone.

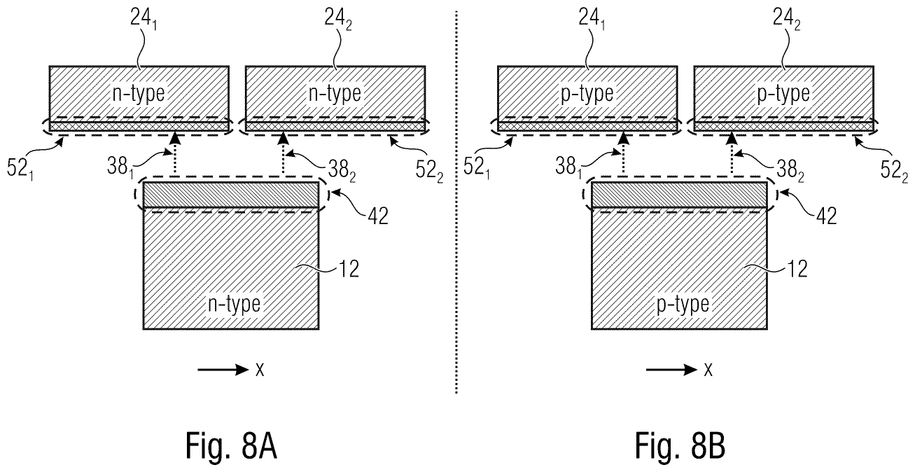

FIG. 8A shows a schematic side sectional view of parts of an MEMS according to an embodiment in which the first semiconductor electrode of the movable element 12, the second semiconductor electrode 24₁ and the third semiconductor electrode 24₃ have the same doping types, here by way of example the n-type. While maintaining the electrical potentials from FIG. 4, this can lead to a space charge zone 42 being formed at the movable element 12 instead of the accumulation zone 44, but this does not oppose the homogeneity of the electrical fields 38₁ and 38₂ along the x-direction, with the result that the advantages in actuating the movement along the x-direction are maintained. In order to obtain the space charge zone, a positive DC+ voltage is advantageously applied to the n-type movable element.

FIG. 8B shows a schematic side sectional view of a configuration according to an embodiment, which is complementary to the configuration from FIG. 8A, in which the movable element 12 and the semiconductor electrodes 241 and 242 are p-doped. Compared to FIG. 8A, the electrical fields 38₁ and 36₂ can be reversed, but this can still allow a homogeneous movement actuation of the movable element 12 along the x-direction. In order to obtain the space charge zone, a negative DC voltage (DC−) is advantageously applied to the p-type movable element.

In the configurations of FIGS. 8A and 8B, the change zones of the movable element on the one hand and of the semiconductor electrodes 24₁ and 24₂ on the other hand can be of different kinds. However, change zones of the same kind can be arranged in a respective MEMS plane, for example an MEMS plane of the semiconductor electrodes 24₁ and 24₂ on the one hand and of the movable element 12 on the other hand. With reference to FIGS. 7A and 8A, the actuating device 54 can be configured to apply a negative (DC) voltage (relative to element 12) to the n-doped semiconductor electrodes 24₁ and 24₂. With reference to FIGS. 7B and 8B, the actuating device 54 can be configured to apply a positive (DC) voltage (relative to element 12) to the semiconductor electrodes 24₁ and 24₂.

It is also possible in this implementation to arrange only one of the electrodes 24₁ or 24₂. In such an implementation, the drive device comprises a first electrode 22 of the movable element 12 and a second electrode 24₁ or 24₂ formed as a doped semiconductor electrode which is arranged opposite to the first electrode 22, configured to generate an electrostatic force between the first electrode 22 and the second electrode 24₁ while generating a first change zone of charge carriers in the second electrode 24₁ or 24₂ for deflecting the movable element 12. Here too, for example, mechanical restoring forces can be used, for example in an implementation of the MEMS as a pump.

However, embodiments provide for combining a further, third electrode, i.e. the electrodes 24₁ and 24₂, with the electrode 22. The third electrode can be configured to generate a second change zone of charge carriers in the third electrode. This third electrode is advantageously arranged opposite to the electrode 22. The MEMS is configured to alternately generate an electrostatic force between the first electrode 22 and the second electrode 24₁ on the one hand, and between the first electrode 22 and the third electrode 24₂ on the other hand, while generating the first change zone of charge carriers in the second electrode 24₁ and the second change zone of charge carriers in the third electrode 24₂ for deflecting the movable element 12. The first change zone and the second change zone are different in this implementation.

In this case, applying a positive or negative constant voltage or DC voltage as described herein is to be understood merely as an example. The DC voltage, also referred to as constant voltage, is not necessarily constant as long as the voltage at the semiconductor electrodes 24₁ and 24₂ is more negative relative to the movable element 12 since an accumulation zone builds up in the semiconductor electrodes 24₁ and 24₂ even then and in the case of a variable voltage.

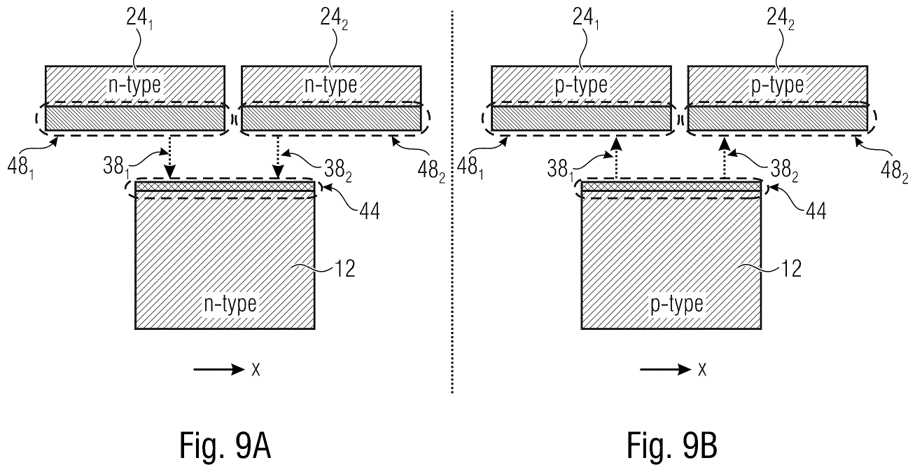

FIGS. 9A and 9B show a respective configuration of the semiconductor electrodes 241 and 242 and of the movable element 12, which corresponds to FIG. 8A and FIG. 8B with respect to the doping, and all of the three elements have a corresponding doping type or a corresponding kind of doping. However, a change in space charge zones and accumulation zones can take place due to a changed voltage which is applied to the elements by means of the actuating device, wherein homogeneity can remain unchanged along the x-direction, which is of advantage for the movement of the movable element 12 along this direction.

Thus, for example, in FIG. 8A, the movable element 12 can be charged positively relative to the electrodes 24₁ and 24₂ in order to obtain the space charge zone 42 at the movable element. In FIG. 9A, the movable element 12 can be charged negatively relative to the electrodes 24₁ and 24₂, wherein an accumulation zone 44 can be obtained on the fin.

The same concept is shown as an embodiment for p-doping in the respective FIGS. 8B and 9B. In FIG. 8B, the electrode of the movable element 12 is charged negatively relative to the electrodes 24₁ and 24₂, wherein a space charge zone is obtained on the fin. In FIG. 9B, the electrode of the movable element 12 is charged positively relative to the electrodes 241 and 24₂ in order to obtain the accumulation zone 44 at the movable element 12.

Embodiments of the present invention provide for a plurality of movable elements to be arranged next to one another along the movement direction x of the movable element 12. Each of the movable elements can be deflected by a pair of semiconductor electrodes at the lid wafer and/or bottom wafer. In the context of embodiments described herein, it is possible but not necessary for the movable element 12 to be arranged movably in-plane with respect to a plane parallel to a substrate plane of the MEMS. A main extension direction of the bottom wafer and/or of the lid wafer can be considered, for example, as such a substrate plane. The movable element 12 can be arranged movably in a cavity of a substrate of the MEMS. The different wafers or planes or MEMS layers allow for an arrangement in which the first semiconductor electrode, the electrode of the movable element, is arranged in a first MEMS layer and the semiconductor electrodes 241 and 242 are arranged in a second, different MEMS layer.

The configurations described above are particularly suitable in MEMS loudspeakers and/or MEMS microphones, but are not limited to this since, for example, pumps, electrostatic drives, such as comb drives, or pressure sensors can also be improved with embodiments.

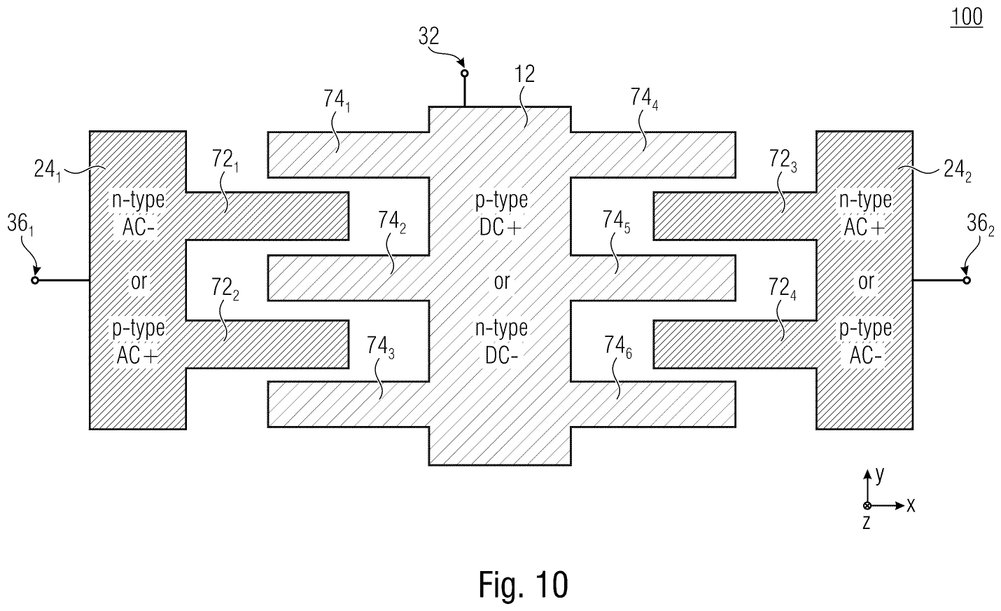

FIG. 10 shows a schematic top view of an MEMS 100 according to an embodiment. The top view shown can easily also be implemented as a side sectional view if this is desired in the context of the MEMS application scenarios.

The semiconductor electrodes 24₁ and 24₂ can be implemented, for example, as finger structures with a plurality of electrode fingers 72, wherein the number of two electrode fingers per semiconductor electrode 24₁ and 24₂ is not limiting. No electrode fingers 72 can also be implemented, only one electrode finger or a number greater than two, for example at least three, at least five, at least ten or more.

Corresponding to the semiconductor electrodes 241 and 242, the movable element 12 can be formed with electrode fingers 741 to 746, wherein the electrode finger structures of the semiconductor electrodes 241 and 242 on the one hand and of the movable element 12 on the other hand can be interdigitated. This configuration serves for obtaining a particularly high degree of electrostatic force, but is not necessary for the implementation of the embodiments described herein.

The semiconductor electrodes 24₁ and 24₂ on the one hand and the movable element 12 on the other hand can have different doping types or kinds of doping and can be applied with a matched potential mixture in order to obtain a deflection of the movable element 12 along a positive and negative x-direction which is as precise as possible.

Thus, according to a first configuration, the semiconductor electrode 241 and the semiconductor electrode 24₂ can be n-doped and the movable element 12 or its electrode(s) can be p-doped. In such a configuration, it is of advantage to apply a positive DC voltage 32 to the movable element 12 and the AC voltages 36₁ and 36_{2,} which are inverted with respect to one another, to the semiconductor electrodes 24₁ and 24_{2.}

According to another configuration, the semiconductor electrodes 24₁ and 24₂ can be p-doped and the movable element 12 or its electrode(s) can be n-doped. A negative DC potential 32 can be applied to the movable electrode 12 and the AC potentials 36₁ and 36₂, which are inverted with respect to one another, can be applied to the semiconductor electrodes 24₁ and 24₂.

According to an embodiment, the MEMS 100 is part of an MEMS comb drive.

Furthermore, in the context of embodiments described herein, it is pointed out that the movable element 12 is possibly but not necessarily provided with a semiconductor-based electrode. Rather, for example, a metallized or metallic electrode can also be used, for instance by arranging it on the movable element 12 or by forming the movable element 12 in a metallic manner. In such a configuration, the first electrode of the movable element and a second electrode formed as a doped semiconductor electrode and a third electrode formed as a doped semiconductor electrode, for instance the semiconductor electrodes 24₁ and 24₂, can be arranged similarly to one another as in the other MEMS described herein. The MEMS is configured to alternately generate an electrostatic force between the first electrode and the second electrode on the one hand, and between the first electrode and the third electrode on the other hand, while generating a first change zone of charge carriers in the second electrode and a second change zone of charge carriers in the third electrode for deflecting the movable element. The change zones in the semiconductor electrodes can be formed to be identical or different.

Such an MEMS can be easily combined with the implementations described in connection with the MEMS having three semiconductor electrodes.

In other words, embodiments described herein allow a development of MEMS, in particular but not exclusively MEMS as are described in WO 2022/117197 A1. With reference to this, according to embodiments, an AC signal, for instance based on a speech signal or a sound signal, is no longer applied to the fin, as is described in the known technology, wherein a signal which is variable over time is described as an AC signal.

While in known systems a positive DC voltage and a negative DC voltage are applied to the first and second lid electrode, which are to be considered to be constant, such known MEMS suffer from the disadvantage that the fin and the lid electrodes can be unfavorable with respect to their actuation on the basis of their semiconductor property. The semiconductor implementation is selected, for example, to allow direct wafer bonding since such a method has a higher alignment accuracy during wafer bonding than other wafer bonding methods. The reason for the disadvantageous actuation is that in semiconductors, when a voltage is applied, the so-called semiconductor effects or field effects occur, such as are used in particular in field effect transistors, FETs. These are based on the fact that charge accumulation is formed from movable charges, electrons or holes, or space charge zones from stationary charges (ion donors/+ or ions/acceptors/−).

If a boron-doped Si semiconductor (p-semiconductor) is considered as an example, the holes/h+ are here majority charge carriers, i.e. the majority, and the electrons e⁻ are the minority charge carriers, i.e. the minority. The boron atoms can in this case represent the acceptors/−. Holes and electrons can be movable, the boron ions are connected to the Si host lattice and therefore stationary.

If no voltage is applied to such a semiconductor or the semiconductor is arranged outside an electrical field, the movable charges are distributed randomly or uniformly in the bulk Si, see FIGS. 5A and 6A. If, however, a voltage is applied or the semiconductor is in an electrical field, then the movable charges will follow the electrical field lines, i.e. the holes along the electrical lines from + to −, the electrons also along the electrical field lines but in the opposite direction from− to +, see FIGS. 5B and 6B. Thus, at the point where, for example, a positive voltage of approximately +10 V was applied (see FIG. 6B), approximately in the form of the voltage U₃, a space charge zone 48, which can also be referred to as space charge zone, RLZ, is formed at its surface from stationary boron ions since charges of the same type repel each other and the holes thus migrate from positively charged boron ions. Where the voltage is negative, for example U2=−10 V/GND, an accumulation zone of movable h+ can be formed at the surface since charge carriers of different signs attract one another.

An analogous situation can arise in an n-doped semiconductor, for example using phosphorus- doped semiconductors. Thus, at the point where U₂ is applied at −10 V, for example, a space charge zone or a space charge zone of stationary P+ ions is formed at the surface and an accumulation of movable e−/electrons is formed at the surface where the voltage of U₂ of +10 V is applied, see FIG. 5B.

If the lid drive is driven as described above, i.e. an AC signal is applied to the fin and DC+ is applied to a first lid electrode and DC− is applied to the second lid electrode, a space charge zone and an accumulation zone are formed at the same time at the surface of the fin, for instance when considering p-type semiconductors with boron-doping, see FIG. 3. Since the h+/holes are very movable, in reality the two regions will not be as cleanly separated as shown in FIG. 3. In reality, a mixture of space charge zone and accumulation zone, which changes from smaller x-values to larger x-values, will be established over the entire fin along the x-direction. This has two major disadvantages. The resulting force acting on the fins will not be ideally linear. Since the difference between the forces a) “force AC/DC−” and b) “force AC/DC+” is no longer linear since the space charge zones/accumulation zones of the different sides of the fins are not equal or act unequally, the result is a deterioration of the total harmonic distortion, THD, in micro loudspeakers. This means that the sound quality decreases, which is of disadvantage. Furthermore, the mixture of space charge zone and accumulation zone will result in an additional electrical capacitance being introduced into the system, namely the capacitance of the electrically non-conductive space charge zone. This will be connected in series with the air capacitance, i.e. the capacitance between the driving electrodes, which represents the main capacitance for the drive. An additional capacitance in series with the main capacitance reduces the total capacitance of the system and thus also the possible capacitance change, which can result in a reduction of the drive force and thus causes a smaller deflection of the fins. At the same time, this results in a lower volume (sound pressure level, SPL).

These disadvantages are avoided by the embodiments described herein.

Field effects or space charge zones and accumulation zones in this case not only form in the fin, the movable element, but also in the electrodes of the lid layer and/or bottom layer, if these also consist of a semiconductor material, which causes additional disadvantages in known systems, but provides for additional degrees of freedom in the context of the embodiments since the disadvantages are overcome.

A possible ideal state could be obtained if the system, i.e. the fin and electrodes, were formed from metal, a partial implementation of the electrodes from metal is within the frame of the embodiments described herein. In metal, such semiconductor effects as space charge zones and accumulation zones and a change between these regions do not occur. Technologically, producing the electrodes on the lid layer and/or bottom layer and the fin or arranging metal on the fin is comparatively complicated and is less advantageous in production processes, in particular in silicon-based MEMS.

The complications can mainly be seen in that a) a very precise adjustment of less than ±1 μm between the lid/bottom and the fin is necessary in the lid drive since the fins are to be positioned symmetrically between the lid electrodes/bottom electrodes and b) the distance between lid electrodes and fin is to be comparatively small, for instance in the order of magnitude of 100 nm to 200 nm.

These two requirements are technologically more difficult to realize with metal materials than semiconductors. This is mainly due to the wafer bonding methods which are to bring the fin and lid/bottom wafer together.

Since the accumulation layers which are closer to the properties of metal in terms of the electrical conductivity properties since they have a very high density of movable charge carriers, it would initially be desirable to generate a semiconductor system in which accumulation zones are mainly formed independently of how the electrical voltage or the electrical fields in the system change during operation. This can initially approximate a state in which all electrodes are produced from metal or semiconductors are dispensed with.

Embodiments of the present invention change known systems in that, for example, adjusting the doping of the semiconductors and of the actuation scheme, i.e. setting the direction of the electrical field, is carried out in such a way that the space charge zones and the accumulation zones in the system are influenced/controlled or taken into account actively.

Depending on the application, the system can be planned and configured or designed such that
1. depletion regions or depletion zones/space charge zones, RLZ, have less influence on the system and all the semiconductors involved have, for example, only accumulation zones at the surfaces, at least those which are used for the drive; or
2. the semiconductors involved have only depletion regions at the surfaces and have no accumulation zones; or
3. a targeted or advantageously selected mixture of space charge zones and accumulation zones is used in the system where, for example, each element, the electrode of the movable element, the first and second semiconductor electrode is controlled either into a depletion region or an accumulation zone, but is not actuated, as in known concepts, in such a way that, for example, the movable element simultaneously has a space charge zone and an accumulation zone, see FIG. 3.

Embodiments, for example for micro loudspeakers, provide for configuring the system in such a way that the space charge zone has less influence on the system and all the semiconductors involved advantageously have only accumulation zones at the surfaces, at least in those regions which are used for driving the movable element.

This can be implemented specifically in such a way that a connection of differently doped semiconductors takes place on the different sides of the drive, see FIGS. 7A-D. For example, the movable element can be of the p-type and the lid/bottom electrodes of the n-type. Alternatively or additionally, the actuation can take place in such a way that only an accumulation zone always occurs on the semiconductor surface, for instance in that control takes place with mutually inverse AC signals in such a way that a constant, for instance positive/+ voltage, is applied to the fin, DC+ and the semiconductor electrodes 24₁ and 24₂ at the lid or bottom obtain the mutually inverse AC⁺/AC⁻ signals. In this case, AC⁺ is the mirror inverse of AC⁻, so that AC⁺ increases with a decreasing AC⁻ and vice versa. If the signal DC+ is considered from the absolute value, it is advantageously always greater than AC⁺ and AC⁻ so that accumulation zones are generated at the surfaces thereof at the same time in p-semiconductors, for instance the fin, and in n-semiconductors of the lid/bottom electrodes, and as a result the electrical field between the movable element/fin and the two driving electrodes points in the same direction.

It may also be realized the other way round, for instance in that the movable element is of the n-type and the lid/bottom electrodes are of the p-type. The actuation can then take place in such a way that the fin obtains a constant negative/− voltage, DC−. The lid/bottom electrodes are supplied with the AC⁺ and AC⁻ signals, wherein their relationship remains unchanged as mirror inverse to one another. It is of advantage for DC− to be always negative in absolute terms (considered relative to AC⁺/AC⁻), but to be greater than AC⁺ and AC⁻ in absolute terms, so that accumulation zones are obtained at the surfaces thereof at the same time in the n-type semiconductors of the fin and in the t-type semiconductors of the lid/bottom electrodes, this means that the electrical field between the movable element/fin and the two electrodes 24₁, 24₂ points in the same direction.

Embodiments of the present invention can be realized with any electrostatic actuators/sensors, for example μ-loudspeakers and/or comb drives. For example, the electrodes 24₁ and 24₂ are of the n-type and the fin of the p-type, as shown in FIG. 10 and FIG. 7A. Alternatively, the electrodes 24₁ and 24₂ can be of the p-type and the movable element of the n-type, as shown, for example, in FIG. 10 or FIG. 7B.

In the abovementioned examples, control can also be selected such that space charge zones are formed on the surface at all three elements or electrodes, as shown, for example, in FIG. 7C-D. FIG. 7C and FIG. 7D show schematic side sectional views of MEMS according to embodiments in which electrodes 24₁ and 24₂, on the one hand, are doped equally, but are doped differently than the semiconductor electrode of the movable element 12 so that, with correct actuation of the semiconductor electrodes, all elements form a space charge zone 42 or 48.

An implementation in that all three electrodes are n-type semiconductors or all three electrodes are p-type semiconductors is also possible in the context of embodiments described herein, see FIGS. 8A-B and FIG. 9A-B. In this case, the accumulation zone forms only on one side, the fin side on the movable element or the electrode side. However, symmetry with respect to the positive/negative x-direction is maintained.

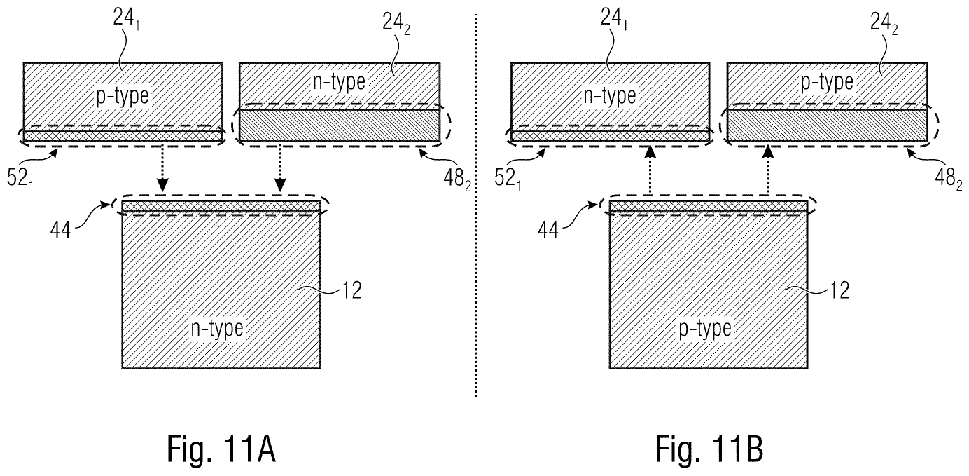

Although they would be more difficult to realize technologically, the following embodiments are also possible, for instance in the context of the fin and one of the two electrodes 24₁/24₂ being operated in the accumulation mode and the other of the electrodes 24₁, 24₂ being operated to form a space charge zone. In this case, the electrodes 24₁ and 24₂ have different kinds of doping with respect to n-type/p-type, wherein the fin can be of the n-type, as shown, for example, in FIG. 11A, or of the p-type, as shown in FIG. 11B. FIGS. 11A-B show schematic side sectional views of MEMS in which electrodes for driving a movable element form different change zones. An accumulation zone 44 is nevertheless formed within the movable element due to the DC actuation, wherein a space charge zone could also be set, and the transition between accumulation zone and space charge zone, as shown in FIG. 3, is avoided.

Alternatively, the electrodes 24₁, 24₂ can have different kinds of doping of the n/p-type and the fin can be of the p-type.

The embodiments described herein can likewise be applied to another MEMS such as a classic comb drive, see FIG. 10, in particular if the combs or electrode receivers comprise or consist of semiconductor materials. In this case, the stator can be considered as a fin and the left and right combs as electrodes 24₁, 24₂.

Embodiments relate to generating only accumulation zones or only space charge zones on the semiconductor elements of the system. This can take place in that the hardware or the MEMS is implemented correspondingly with respect to the semiconductor kinds of doping. Elements which form the two sides of the drive can have different doping types, if the fin is of the p-type, then the lid/bottom electrodes are advantageously of the n-type. Alternatively, if the fin is of the n-type, then the lid/bottom electrodes are advantageously of the p-type.

Embodiments also relate to the actuation, i.e. the software aspect. The actuation advantageously takes place in such a way that a constant DC potential is applied to the fin and AC⁺ and AC⁻ signals, which are implemented inversely with respect to one another, are applied to the lid/bottom electrodes.

Although some aspects have been described in connection with an apparatus, it is to be understood that these aspects also represent a description of the corresponding method, with the result that a block or a component of an apparatus is also to be understood as a corresponding method step or feature of a method step. In analogy, aspects described in connection with or as a method step also represent a description of a corresponding block or detail or feature of a corresponding apparatus.

Depending on specific implementation requirements, embodiments of the invention, for example for programming the hardware and/or for applying AC/DC potentials, can be implemented in hardware or in software. The implementation can be carried out using a digital storage medium, for example a floppy disk, a DVD, a Blu-ray disc, a CD, ROM, PROM, EPROM, EEPROM or a FLASH memory, a hard disk or another magnetic or optical memory, on which electronically readable control signals are stored which can interact or interact with a programmable computer system such that the respective method is performed. The digital storage medium can therefore be computer-readable. Thus, some embodiments according to the invention comprise a data carrier which has electronically readable control signals which are capable of interacting with a programmable computer system such that one of the methods described herein is performed.

In general, embodiments of the present invention can be implemented as a computer program product with program code, wherein the program code is effective to perform one of the methods when the computer program product runs on a computer. The program code can, for example, also be stored on a machine-readable carrier.

Other embodiments comprise the computer program for performing one of the methods described herein, wherein the computer program is stored on a machine-readable carrier.

In other words, an embodiment of the method according to the invention is thus a computer program which has program code for performing one of the methods described herein when the computer program runs on a computer. A further embodiment of the methods according to the invention is thus a data carrier (or a digital storage medium or a computer-readable medium) on which the computer program for performing one of the methods described herein is recorded.

A further embodiment of the method according to the invention is thus a data stream or a sequence of signals which represents or represent the computer program for performing one of the methods described herein. The data stream or the sequence of signals can, for example, be configured to be transferred via a data communication link, for example via the Internet.

A further embodiment comprises a processing device, for example a computer or a programmable logic component, which is configured or adjusted to perform one of the methods described herein.

A further embodiment comprises a computer on which the computer program for performing one of the methods described herein is installed.

In some embodiments, a programmable logic device (for example a field-programmable gate array, FPGA) can be used to perform some or all of the functionalities of the methods described herein. In some embodiments, a field-programmable gate array can interact with a microprocessor to perform any of the methods described herein. Generally, in some embodiments, the methods are performed by any hardware apparatus. This can be universally usable hardware such as a computer processor (CPU) or hardware specific to the method, for example an ASIC.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. An MEMS comprising:
a movable element; and
a drive device comprising a first doped semiconductor electrode of the movable element and a second doped semiconductor electrode which is arranged opposite to the first semiconductor electrode and configured to generate an electrostatic force between the first semiconductor electrode and the second semiconductor electrode while generating a first change zone of charge carriers in the first semiconductor electrode and a second change zone of charge carriers in the second semiconductor electrode for deflecting the movable element.

2. The MEMS according to claim 1, further comprising a third doped semiconductor electrode which is arranged opposite to the first semiconductor electrode together with the second doped semiconductor electrode, wherein the semiconductor electrodes are configured to alternately generate an electrostatic force between the first semiconductor electrode and the second semiconductor electrode on the one hand, and between the first semiconductor electrode and the third semiconductor electrode on the other hand, while generating the first change zone of charge carriers in the first semiconductor electrode and the second change zone of charge carriers in the second semiconductor electrode and a third change zone of charge carriers in the third semiconductor electrode for deflecting the movable element;
wherein the second change zone and the third change zone are of the same kind.

3. The MEMS according to claim 2, wherein the second change zone and the third change zone are an accumulation zone; or wherein the second change zone and the third change zone are a space charge zone.

4. The MEMS according to claim 2, wherein the first change zone, the second change zone and the third change zone are equal along a longitudinal extension direction or transverse extension direction of the movable element.

5. The MEMS according to claim 2, wherein the first change zone, the second change zone and the third change zone are of the same kind.

6. The MEMS according to claim 1, comprising an actuating device which is configured to actuate the drive device, wherein the actuating device is configured to apply a DC voltage to the first semiconductor electrode and to apply a first alternating voltage to the second semiconductor electrode; and to apply a second alternating voltage to a third semiconductor electrode.

7. The MEMS according to claim 6, wherein the first alternating voltage is inverse to the second alternating voltage.

8. The MEMS according to claim 6, wherein a maximum absolute amplitude of the first alternating voltage and/or the second alternating voltage is smaller than an absolute amplitude of the DC voltage.

9. The MEMS according to claim 2, wherein at least two elements from the group of the first semiconductor electrode, the second semiconductor electrode and the third semiconductor electrode comprise different doping types.

10. The MEMS according to claim 9, wherein the first semiconductor electrode comprises a different doping type with respect to the second and/or third semiconductor electrode.

11. The MEMS according to claim 2, wherein the first semiconductor electrode, the second semiconductor electrode and the third semiconductor electrode comprise the same doping types.

12. The MEMS according to claim 11, wherein the first change zone on the one hand and the second change zone and the third change zone on the other hand are of different kinds.

13. The MEMS according to claim 11, wherein the MEMS comprises an actuating device configured to actuate the drive device;
wherein the semiconductor electrodes are n-doped and the actuating device is configured to apply a negative DC voltage to the first semiconductor electrode; or
wherein the semiconductor electrodes are p-doped and the actuating device is configured to apply a positive DC voltage to the first semiconductor electrode.

14. The MEMS according to claim 1, comprising a plurality of movable elements arranged next to one another along a movement direction of the movable element.

15. The MEMS according to claim 1, wherein the movable element is arranged movably in-plane with respect to a plane parallel to a substrate plane of the MEMS.

16. The MEMS according to claim 1, wherein the movable element is arranged in a cavity of a substrate of the MEMS.

17. The MEMS according to claim 1, wherein the first semiconductor electrode is arranged in a first MEMS layer and the second semiconductor electrode and a third semiconductor electrode are arranged in a second MEMS layer.

18. The MEMS according to claim 17, which is part of an MEMS loudspeaker.

19. The MEMS according to claim 1, wherein the first semiconductor electrode is arranged between the second semiconductor electrode and a third semiconductor electrode.

20. The MEMS according to claim 19, which is part of an MEMS comb drive.

21. The MEMS according to claim 1, further comprising a third doped semiconductor electrode which is arranged opposite to the first semiconductor electrode together with the second doped semiconductor electrode, wherein the semiconductor electrodes are configured to alternately generate an electrostatic force between the first semiconductor electrode and the second semiconductor electrode on the one hand, and between the first semiconductor electrode and the third semiconductor electrode on the other hand, while generating the first change zone of charge carriers in the first semiconductor electrode and the second change zone of charge carriers in the second semiconductor electrode and a third change zone of charge carriers in the third semiconductor electrode for deflecting the movable element;
wherein the second change zone and the third change zone are of the same kind;
wherein the first semiconductor electrode, the second semiconductor electrode and the third semiconductor electrode comprise the same doping types;
wherein the MEMS comprises an actuating device configured to actuate the drive device; and wherein the semiconductor electrodes are n-doped and the actuating device is configured to apply a negative DC voltage to the first semiconductor electrode; or wherein the semiconductor electrodes are p-doped and the actuating device is configured to apply a positive DC voltage to the first semiconductor electrode.

22. An MEMS comprising:
a movable element; and
a drive device comprising a first electrode of the movable element and a second electrode formed as a doped semiconductor electrode which is arranged opposite to the first electrode and configured to generate an electrostatic force between the first electrode and the second electrode while generating a first change zone of charge carriers in the second electrode and for deflecting the movable element.

23. The MEMS according to claim 22, further comprising
a third electrode formed as a doped semiconductor electrode which is arranged opposite to the first electrode together with the second electrode and is configured to generate a second change zone of charge carriers in the third electrode;
wherein the MEMS is configured to alternately generate an electrostatic force between the first electrode and the second electrode on the one hand, and between the first electrode and the third electrode on the other hand, while generating the first change zone of charge carriers in the second electrode and the second change zone of charge carriers in the third electrode for deflecting the movable element;
wherein the first change zone and the second change zone are different.
